(19) United States
(12) Patent Application Publication
(10) Pub. No.: US 2026/0291509 A1
(43) Pub. Date: Sep. 24, 2026

(54) DIGITAL CLOCK FREQUENCY TRACKER AND HIGH-SPEED SERIAL INTERFACE CHIP

(71) Applicant: JOYWELL SEMICONDUCTOR (SHANGHAI) CO., LTD., Shanghai (CN)

(72) Inventors: Fei FENG, Shanghai (CN); Haonan WANG, Shanghai (CN)

(21) Appl. No.: 19/161,928

(22) PCT Filed: Feb. 28, 2024
(86) PCT No.: PCT/CN2024/078958

§ 371 Date: Sep. 3, 2025

(30) Foreign Application Priority Data
Mar. 3, 2023 (CN) 202310199151.3

(51) Int. Cl. H03L 7/195; H03L 7/091; H03L 7/107; H03L 7/199

(52) U.S. Cl. CPC H03L 7/195; H03L 7/091; H03L 7/107; H03L 7/199

(57) ABSTRACT

A digital clock frequency tracker includes a counter-based frequency discriminator, which is used for acquiring a frequency-divided recovered clock signal, which is obtained from a clock signal recovered by a clock-data recovery circuit at a receiving end and a divided local clock signal which is generated by a phase-locked loop of a transmitting end and has been subjected to frequency division, for setting corresponding target values, for performing sampling on a count value of the recovered clock signal after a count value of the local clock signal reaches a target value, and for obtaining frequency offset information; a phase detector, which is used for setting a frequency division coefficient according to the frequency division ratio of the recovered clock signal to the local clock signal, for performing oversampling on the recovered clock signal by using the local clock signal and according to the frequency division coefficient.

### TECHNICAL FIELD

The present application relates to the field of integrated circuit technology, and in particular to a digital clock frequency tracker and a high-speed serial interface chip.

### BACKGROUND ART

This section aims to provide background or context for the implementation of the application stated in the claims. The description here should not be considered prior art merely because it is included in this section.

The function of high-speed serial interface chips used in retimers is to enhance the signal received by a receiver and then transmit the enhanced signal to the next-level device via a transmitter on the other side. Because the local receiver/transmitter and the peripheral devices use different reference clocks generated by different crystal oscillators as clock sources, the local receiver/transmitter needs, in addition to using a phase-locked loop (PLL) to generate the high-speed clock, to adopt an additional clock-frequency tracking scheme to ensure that the high-speed clock for receiving/transmitting data matches that of the counterpart peripheral device, thereby ensuring correct data reception, conditioning (e.g., retiming/equalization), and transmission. On the receiver side of the high-speed serial interface chip, CDR (clock data recovery) technology is generally used to directly recover the clock information from the received serial signal and use it as the local high-speed clock for receiving data. Because the transmitter also requires a clock of the same frequency for serial data transmission, this high-speed clock needs to be transmitted from the receiver to the transmitter for serial data transmission. In high-speed serial interface chips, transmitting the high-speed clock consumes significant power and is easily affected by factors such as crosstalk and noise. Currently, two schemes are used for this transmission:
1. The high-speed clock recovered from the received data by the receiver clock-data recovery circuit is directly transmitted to the transmitter for high-speed serial data transmission. This solution requires the transmission of a high-speed clock signal, and as the chip's data transmission rate increases, the frequency of the clock signal also increases, making it increasingly difficult to implement in applications with higher transmission rate. Because the receiver and transmitter may be physically far apart within the chip, transmitting this high-speed clock signal requires multiple buffers to ensure clock transmission quality, which in turn consumes a lot of power. Furthermore, to ensure high-speed clock transmission performance, the clock routing channels must be well-designed and isolated, which increases the design difficulty and the area consumed by the clock channels.
2. The high-speed clock recovered from the received data by the receiver's clock-data recovery circuit is frequency-divided and then transmitted to the transmitter; the transmitter's PLL locks to this clock as a reference, and the transmitter uses the PLL's locked output as the high-speed transmit clock. This solution reduces the frequency of the recovered clock transmitted from the receiver to the transmitter and thus can reduce clock-distribution power to some extent; however, because the clock delivered to the transmitter is used as the PLL reference, the integrity of the clock-distribution path remains critical to transmit performance, and the routing/channel design remains challenging.

The present invention proposes a high-performance, low-power solution for enabling the transmission frequency of serial data at a transmitter to track the reception frequency of data at a receiver.

### SUMMARY OF THE INVENTION

An object of the present application is to provide a digital clock frequency tracker that greatly reduces the design complexity of clock distribution and to suppress high-frequency noise in the recovered clock via a digitally implemented low-pass filter, thereby improving transmit-side performance.

The present application discloses a digital clock frequency tracker, comprising:
a counter-based frequency discriminator, configured to receive a frequency-divided recovered clock signal from a clock-data recovery circuit at a receiver and a frequency-divided local clock signal from a phase-locked loop at a transmitter, set corresponding target values according to a frequency ratio of the recovered clock signal to the local clock signal, sample a count value of the recovered clock signal after a count value of the local clock signal reaches its corresponding target value, and obtain frequency offset information by comparing the count value of the recovered clock signal with the count value of the local clock signal;
a phase detector, configured to receive the divided recovered clock signal and the divided local clock signal, set a frequency division coefficient according to the frequency ratio of the recovered clock signal to the local clock signal, perform oversampling on the recovered clock signal using the local clock signal according to the frequency division coefficient, and obtain phase information based on sampling results; and
a digital low-pass filter, configured to generate a frequency control word according to the frequency offset information and the phase information and their respective gains, and output the frequency control word to the phase-locked loop at the transmitting end.

In a preferred embodiment, the digital clock frequency tracker further comprises:
a frequency anomaly monitoring module, configured to receive the divided recovered clock signal and the divided local clock signal, set corresponding target values according to the frequency ratio of the recovered clock signal to the local clock signal, sample a count value of the recovered clock signal after a count value of the local clock signal reaches its corresponding target value, and when the difference between the count value of the recovered clock signal and the corresponding target value exceeds a predetermined range, disable the digital low-pass filter, and when the difference between the count value of the recovered clock signal and the corresponding target value is within the predetermined range, enable the digital low-pass filter.

In a preferred embodiment, the target value of the recovered clock signal is four, six, or eight times the target value of the local clock signal, and the target values of the recovered clock signal and the local clock signal set in the frequency anomaly monitoring module are less than those set in the counter-based frequency discriminator.

In a preferred embodiment, the counter-based frequency discriminator is further configured to reset the count value of the recovered clock signal and the count value of the local clock signal after sampling the count value of the recovered clock signal.

In a preferred embodiment, the target value of the recovered clock signal is four, six, or eight times the target value of the local clock signal.

In a preferred embodiment, the phase detector performs oversampling on the recovered clock signal by an integer multiple of four using the local clock signal according to the frequency division coefficient, and when the sampling result is 000, 010, 101, or 111, the phase detection result is 0; when the sampling result is 001 or 110, the phase detection result is −1, and when the sampling result is 011 or 100, the phase detection result is 1, and the phase detector sequentially outputs the phase detection results.

In a preferred embodiment, the phase detector performs oversampling on the recovered clock signal by an integer factor that is not a multiple of four using the local clock signal according to the frequency division coefficient, when the sampling result is 000, 010, 101, or 111, the phase detection result is 0, when the sampling result is 001 or 110, the phase detection result is −1, and when the sampling result is 011 or 100, the phase detection result is 1, and the phase detector sequentially outputs the phase detection results starting from the first phase detection result with an interval of the integer factor that is not a multiple of four, and discards other phase detection results.

In a preferred embodiment, the phase detector performs oversampling on the recovered clock signal by an integer factor that is not a multiple of four using the local clock signal according to the frequency division coefficient, wherein the oversampling is six-times oversampling.

The present application also discloses a high-speed serial interface chip, comprising: a clock-data recovery circuit at a receiving end, configured to recover a high-speed clock of the receiving end;
a first frequency divider, configured to divide the recovered high-speed clock to obtain a divided recovered clock signal;
a phase-locked loop at a transmitting end, configured to generate the high-speed clock of the transmitting end;
a second frequency divider, configured to divide the high-speed clock of the transmitting end to obtain a divided local clock signal; and
the digital clock frequency tracker as described above.

The embodiments of the present application have the following beneficial effects:
1. The digital signal of the frequency control word is directly transmitted to the transmitter, so there is no need to use an analog signal to transmit the clock between the receiver and the transmitter, which simplifies the design difficulty of clock transmission and reduces the power consumption of the clock transmission path.
2. The high-frequency noise in the recovered clock can be suppressed by the low-pass filter implemented in the digital circuit, thereby improving the transmitter performance.
3. In the digital circuit, the frequency anomaly monitoring module can be used to maintain the output frequency of the transmitter phase-locked loop in an abnormal state, thereby avoiding the transmitter phase-locked loop from losing lock, so that the transmitter can quickly resume data transmission after the receiver returns to normal.
4. The digital circuit is used to discriminate the frequencies of the receiver's recovered clock and the transmitter's local clock; the frequency information can be read by software and converted into a frequency-control word to directly program the transmitter PLL output frequency, thereby enabling software control.

This specification contains numerous technical features distributed among various technical solutions. Listing all possible combinations of these technical features (i.e., technical solutions) would make the specification too lengthy. To avoid this problem, the technical features disclosed in the above-mentioned invention content, the technical features disclosed in various embodiments and examples in the following text, and the technical features disclosed in the drawings can all be freely combined to form various new technical solutions (which should be considered as already disclosed in this specification), unless such combinations of technical features are technically infeasible. For example, if feature A+B+C is disclosed in one example and feature A+B+D+E is disclosed in another example, and features C and D are equivalent technical means that serve the same purpose, only one of them can be chosen for technical reasons and cannot be used simultaneously. Feature E can be combined with feature C from a technical perspective. Therefore, the A+B+C+D solution should not be considered as already disclosed because it is technically infeasible, while the A+B+C+E solution should be considered as already disclosed.

### BRIEF DESCRIPTION OF THE DRAWINGS

FIG. 1 is a schematic structural diagram of a digital clock frequency tracker according to an embodiment of the present application.

FIG. 2 is a schematic diagram of the working sequence of a counter-based frequency discriminator according to an embodiment of the present application.

FIG. 3 is a schematic diagram illustrating the operating principle of a phase detector according to an embodiment of the present application.

FIG. 4 is a schematic diagram illustrating the operating principle of a phase detector according to another embodiment of the present application.

### DESCRIPTION OF REFERENCE NUMERALS

100: digital clock frequency tracker
101: counter-based frequency discriminator
102: phase detector
103: digital low-pass filter
104: frequency anomaly monitoring module
105: clock-data recovery circuit
106: a first frequency divider
107: phase-locked loop
108: a second frequency divider

### DETAILED DESCRIPTION

In the following description, numerous technical details are set forth in order to provide the readers with a better understanding of the present application. However, those skilled in the art can understand that the technical solutions claimed in the present application can be implemented without these technical details and various changes and modifications based on the following embodiments.

The following is a summary of some of the innovative features of the embodiments of the application:

The present invention proposes a method for extracting frequency information from the clock recovered by a receiver clock-data recovery circuit using a digital circuit, adjusting the output frequency of the transmitter phase-locked loop by changing the frequency control word of the transmitter phase-locked loop, thereby achieving the purpose of tracking the data transmission frequency of the transmitter with the data reception frequency of the receiver. The solution of extracting frequency information using digital circuits allows the digital signal to be directly transmitted to the transmitter, eliminating the need to transmit an analog clock between the receiver and transmitter, significantly reducing the design complexity of clock transmission. Furthermore, a low-pass filter implemented in the digital circuit can suppress high-frequency noise in the recovered clock, thereby improving transmitter performance.

In order to make the objects, technical solutions and advantages of the present application clearer, embodiments of the present application will be further described in detail below with reference to the accompanying drawings.

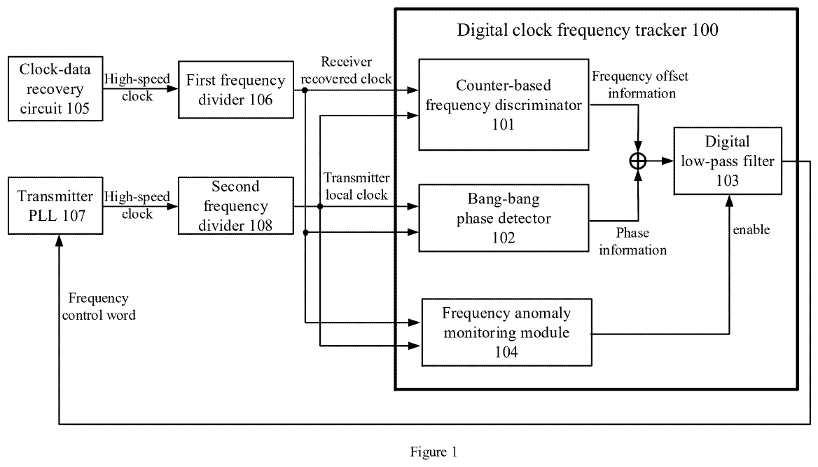

An embodiment of the present application relates to a digital clock frequency tracker, the structure of which is shown in FIG. 1, the digital clock frequency tracker 100 comprises a counter-based frequency discriminator 101, a phase detector 102, and a digital low-pass filter 103. The counter-based frequency discriminator 101 and the phase detector 102 are respectively coupled to the digital low-pass filter 103. The counter-based frequency discriminator 101 is used to acquire a divided recovered clock signal which is recovered by a clock-data recovery circuit 105 at a receiving end (receiver) and has been subjected to frequency division by a first frequency divider 106 and a divided local clock signal which is generated by a phase-locked loop 107 of a transmitting end (transmitter) and has been subjected to frequency division by a second frequency divider 108. The counter-based frequency discriminator 101 sets corresponding target values based on the frequency ratio of the recovered clock signal to the local clock signal. After a count value of the local clock signal reaches the corresponding target value, a count value of the recovered clock signal is sampled, and frequency offset information is obtained by comparing the count value of the recovered clock signal with the count value of the local clock signal. The phase detector 102 receives the divided recovered clock signal which is recovered by the clock-data recovery circuit 105 of the receiving end and has been subjected to frequency division by the first frequency divider 106 and the divided local clock signal which is generated by a phase-locked loop 107 of the transmitting end and has been subjected to frequency division by the second frequency divider 108, and sets a frequency division coefficient based on the ratio of the recovered clock signal to the local clock signal. The phase detector 102 then performs oversampling on the recovered clock signal using the local clock signal according to the frequency division coefficient and obtains phase information based on the sampling results. The digital low-pass filter 103 is used to obtain a frequency control word based on the frequency offset information, the phase information, and their respective gains, and then output the frequency control word to the phase-locked loop 107 of the transmitting end.

At the receiving end, the clock recovered from the received serial data by the clock-data recovery circuit 105 is divided by the first frequency divider 106 and transmitted to the digital clock frequency tracker 100, implemented by a digital circuit, as a reference clock input. Furthermore, at the transmitting end, the high-speed clock generated by the transmitter phase-locked loop 107 is divided by the second frequency divider 108 and transmitted to the digital clock frequency tracker 100 as the local clock to be adjusted. After performing frequency and phase discrimination on the two input clocks, the digital clock frequency tracker 100 generates the frequency control word and transmits it to the transmitter phase-locked loop 107 to control the frequency of the output clock.

In the digital clock frequency tracker 100, the frequency information extraction function is implemented by two submodules: the counter-based frequency discriminator 101 and the bang-bang phase detector 102. In the implementation of the counter-based frequency discriminator 101, the target count values for the recovered clock from the receiving end and the local clock from the transmitting end are firstly configured based on the data transmission rate of the receiver and transmitter and the frequency ratio on the two high-speed clock paths. Then, the reset signals for two counters driven by the recovered clock from the receiving end and the local clock from the transmitting end, respectively, are released simultaneously to ensure that both counters start operating simultaneously. Finally, when the count value of counter for the local clock from the transmitting end reaches the target value, a pulse signal is generated to sample the counter for the recovered clock from the receiving end and the sampled count value is compared with the corresponding target value to obtain frequency offset information. After being multiplied by a configurable gain, the frequency offset information is fed into the digital low-pass filter 103, which then generates the frequency control word for the transmitter phase-locked loop 107. The full value of the frequency offset information, or only its sign, can be selectively configured to be used as the increment of the frequency control word.

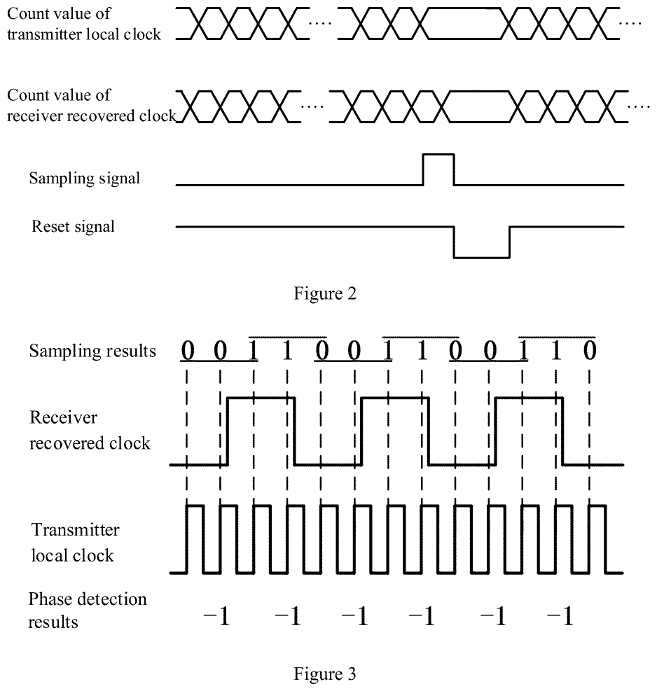

The working sequence of the counter-based frequency discriminator 101 is shown in FIG. 2. Since the recovered clock from the receiving end is affected by the receiving end data and has uncertainty, the local clock from the transmitting end is used as the master clock for the counter-based frequency discriminator logic to generate sampling signals and counter reset signals. In one embodiment, after sampling the count value of the recovered clock signal, the counter-based frequency discriminator 101 is also used to reset the count value of the recovered clock signal and the count value of the local clock signal. In one embodiment, the target value of the recovered clock signal is four times, six times, eight times, etc., that of the local clock signal. It should be understood that in other embodiments of the present application, other multiples may be used, such as two times, five times, and the like.

The operating principle of the bang-bang phase detector 102 is shown in FIG. 3. Similar to the counter-based frequency discriminator 101, the bang-bang phase detector 102 also uses the local clock from the transmitting end as the master clock for its digital logic. By configuring different frequency division coefficients of the dividers, the frequency of the local clock from the transmitting end used by the bang-bang phase detector 102 is four times that of the recovered clock from the receiving end. The bang-bang phase detector 102 uses the local clock from the transmitting end to perform four times oversampling on the recovered clock from the receiving end, and determines the relative phase relationship between the two clocks based on the sampling results. The relationship between the sampling results, the phase relationship, and the bang-bang phase detector output is shown in Table 1. When the sampling result of the bang-bang phase detector is 000, 010, 101 or 111, it indicates that the phase relationship is incorrect, the phase detection result is 0, and the bang-bang phase detector outputs 0. When the sampling result of the bang-bang phase detector is 001 or 110, it indicates that the recovered clock from the receiving end leads the local clock from the transmitting end, the phase detection result is −1, and the bang-bang phase detector outputs −1. When the sampling result is 011 or 100, it indicates that the recovered clock from the receiving end lags the local clock from the transmitting end, the phase detection result is 1, and the bang-bang phase detector outputs 1. The phase information of the two clocks is multiplied by configurable gains and then fed into the digital low-pass filter 103, which then generates the frequency control word for the transmitter phase-locked loop 107.

TABLE 1
Relationship between sampling results, phase
relationship and phase detection results

| Sampling results | Phase relationship | Phase detection results |
|---|---|---|
| 000 | Error | 0 |
| 001 | Phase lead | −1 |
| 010 | Error | 0 |
| 011 | Phase lag | +1 |
| 100 | Phase lag | +1 |
| 101 | Error | 0 |
| 110 | Phase lead | −1 |
| 111 | Error | 0 |

Other configurations may be employed in other embodiments of the present application, but it is necessary to ensure that the oversampling multiple on the recovered clock from the receiving end using the local clock from the transmitting end in the bang-bang phase detector 102 is greater than two times, for example, four times, six times, eight times, and so on. If the oversampling multiple is an integer multiple of 4, the sampling results (phase detection results) do not need to be screened, and the bang-bang phase detector outputs the phase detection results sequentially. If it is not an integer multiple of 4, the sampling results (phase detection results) need to be screened before use. The screening principle is to convert the frequencies of the recovered clock from the receiving end and the local clock from the transmitting end into fractional form, for example, A/B, where A and B are both integers. Then, the first phase detection result in each group of N phase detection results is valid data, and the remaining N−1 phase detection results are invalid, with N being the least common multiple of A and B.

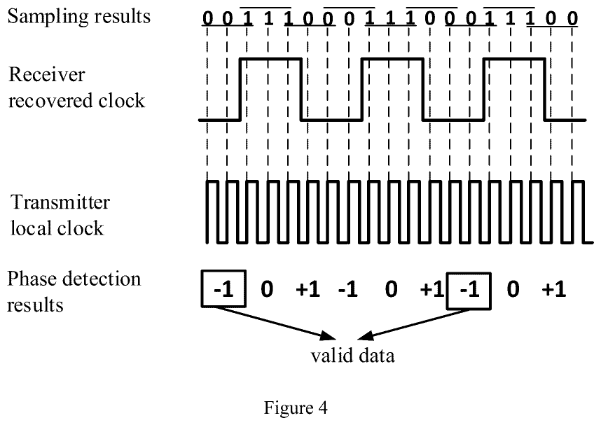

The following takes six times oversampling as an example, the operating principle of the bang-bang phase detector 102 is shown in FIG. 4. When the sampling result of the bang-bang phase detector is 000, 010, 101, or 111, it indicates that the phase relationship is incorrect, the phase detection result is 0. When the sampling result of the bang-bang phase detector is 001 or 110, it indicates that the recovered clock from the receiving end leads the local clock from the transmitting end, the phase detection result is −1. When the sampling result is 011 or 100, it indicates that the recovered clock from the receiving end lags the local clock from the transmitting end, the phase detection result is 1. With six times oversampling, the frequency ratio between the recovered clock from the receiving end and the local clock from the transmitting end is 1/6. Therefore, A=1, B=6, and N is the least common multiple of 1 and 6, i.e., 6. the phase detector 102 outputs every sixth phase detection result (starting from the first) and discards the rest. This means that the first of every six phase detection results is valid data, and the remaining data is discarded.

In the present invention, the frequency and phase detection results output by the two submodules of the counter-based frequency discriminator 101 and the bang-bang phase detector 102 are multiplied by their independently configured gains and then fed into the parameter-configurable digital low-pass filter 103. The digital low-pass filter 103 generates the frequency control word of the transmitter phase-locked loop 107 and outputs the frequency control word to the transmitter phase-locked loop 107.

Since the recovered clock from the receiving end is affected by the receiving end data and has uncertainty, the present application comprises a frequency anomaly monitoring module 104 to detect any anomalies in the frequency of the recovered clock from the receiving end. The frequency anomaly monitoring module 104 is used to obtain the divided recovered clock signal which is recovered by the clock-data recovery circuit 105 of the receiving end and has been subjected to frequency division by the first frequency divider 106 and the divided local clock signal which is generated by a phase-locked loop 107 of the transmitting end and has been subjected to frequency division by the second frequency divider 108, and sets target values based on the frequency ratio of the recovered clock signal to the local clock signal. After a count value of the local clock signal reaches its corresponding target value, the frequency anomaly monitoring module 104 samples a count value of the recovered clock signal. when the difference between the count value of the recovered clock signal and the corresponding target value exceeds a predetermined range, the frequency anomaly monitoring module 104 disables the digital low-pass filter 103. Furthermore, when the difference between the count value of the recovered clock signal and the corresponding target value is within the predetermined range, the frequency anomaly monitoring module 104 enables the data low-pass filter 103. In one embodiment, the target value of the recovered clock signal from the receiving end in the frequency anomaly monitoring module 104 may be four, six, or eight times, etc., the target value of the local clock signal from the transmitting end. It should be understood that in other embodiments of the present application, it may be other times, for example, two times, five times, etc.

The working principle of the frequency anomaly monitoring module 104 is the same as that of the counter-based frequency discriminator 101, but with lower precision and higher bandwidth. The target value of the recovered clock signal from the receiving end and the target value of the local clock signal from the transmitting end in the frequency anomaly monitoring module 104 are set less than the target value of the recovered clock signal from the transmitting end and the target value of the local clock signal from the transmitting end in the count frequency demodulator 101, so that the counting cycle becomes shorter and the frequency deviation can be calculated more quickly through the counting results. Therefore, it is possible to quickly detect whether the frequency of the recovered clock frequency from the receiving end deviates significantly from the expected value to achieve high bandwidth. If the frequency of the recovered clock from the receiving end is abnormal, the frequency anomaly monitoring module may turn off the enable signal of the digital filter, and the frequency control word output by the digital filter may remain unchanged until the frequency of the recovered clock from the receiving end returns to normal.

In summary, the present invention does not directly transmit the analog clock from the receiving end to the transmitting end to achieve frequency tracking. Instead, it uses a digital circuit to extract the frequency information from the recovered clock from the receiving end and transmits this digital signal to the transmitting end to complete frequency tracking. In the digital circuit, the frequency anomaly monitoring module can be used to maintain the output frequency of the transmitter phase-locked loop (PLL) in abnormal conditions, preventing the transmitter PLL from losing lock and allowing the transmitter to quickly resume data transmission after the receiver returns to normal.

It should be noted that in this specification of the application, relational terms such as the first and second, and so on are only configured to distinguish one entity or operation from another entity or operation, and do not necessarily require or imply any such actual relationship or order between these entities or operations. Furthermore, the term “comprises” or “comprising” or “includes” or any other variations thereof is intended to encompass a non-exclusive inclusion, such that a process, method, article, or device that comprises a multiple elements includes not only those elements but also other elements, or elements that are inherent to such a process, method, item, or device. Without more restrictions, the element defined by the phrase “comprise(s) a/an” does not exclude that there are other identical elements in the process, method, item or device that includes the element. In this specification of the application, if it is mentioned that an action is performed according to an element, it means the meaning of performing the action at least according to the element, and includes two cases: the action is performed only on the basis of the element, and the action is performed based on the element and other elements. Multiple, repeatedly, various, etc., expressions include 2, twice, 2 types, and 2 or more, twice or more, and 2 types or more types.

The term “coupled to” and its derivatives may be used herein. “Coupled” may mean that two or more elements are in direct physical or electrical contact. However, “coupled” may also mean that two or more elements are in indirect contact with each other, but still cooperate or interact with each other, and may mean that one or more other elements are coupled or connected between the elements referred to as being coupled to each other.

The specification includes combinations of the various embodiments described herein. Separate references to embodiments (such as “an embodiment” or “some embodiments” or “preferred embodiments”) do not necessarily refer to the same embodiment; however, these embodiments are not mutually exclusive unless indicated as mutually exclusive or clearly mutually exclusive by those skilled in the art. It should be noted that unless the context clearly indicates or requires otherwise, the word “or” is used in this specification in a non-exclusive sense.

All documents mentioned in this specification are considered to be included in the disclosure of the application as a whole, so that they can be used as a basis for modification when necessary. In addition, it should be understood that the above descriptions are only preferred embodiments of this specification, and are not intended to limit the protection scope of this specification. Any modification, equivalent replacement, improvement, etc. made within the spirit and principle of one or more embodiments of this specification should be included in the protection scope of one or more embodiments of this specification.

1. A digital clock frequency tracker, comprising:
a counter-based frequency discriminator, configured to acquire a recovered clock signal obtained by frequency-dividing a clock signal recovered by a clock-data recovery circuit at a receiving end, and a local clock signal obtained by frequency-dividing a clock signal generated by a phase-locked loop at a transmitting end, set corresponding target values according to a frequency ratio of the recovered clock signal to the local clock signal, sample a count value of the recovered clock signal after a count value of the local clock signal reaches the corresponding target value, and obtain frequency offset information by comparing the count value of the recovered clock signal with the count value of the local clock signal;
a phase detector, configured to receive the divided recovered clock signal and the divided local clock signal, set a frequency division coefficient according to the frequency ratio of the recovered clock signal to the local clock signal, perform oversampling on the recovered clock signal using the local clock signal according to the frequency division coefficient, and obtain phase information based on sampling results; and
a digital low-pass filter, configured to generate a frequency control word according to the frequency offset information and the phase information and their respective gains, and output the frequency control word to the phase-locked loop at the transmitting end.

2. The digital clock frequency tracker according to claim 1, further comprising:
a frequency anomaly monitoring module, configured to receive the divided recovered clock signal and the divided local clock signal, set corresponding target values according to the frequency ratio of the recovered clock signal to the local clock signal, sample a count value of the recovered clock signal after a count value of the local clock signal reaches its corresponding target value, and when the difference between the count value of the recovered clock signal and the corresponding target value exceeds a predetermined range, disable the digital low-pass filter, and when the difference between the count value of the recovered clock signal and the corresponding target value is within the predetermined range, enable the digital low-pass filter.

3. The digital clock frequency tracker according to claim 2, wherein in the frequency anomaly monitoring module the target value of the recovered clock signal is four, six, or eight times the target value of the local clock signal, and the target values of the recovered clock signal and the local clock signal set in the frequency anomaly monitoring module are less than those set in the counter-based frequency discriminator.

4. The digital clock frequency tracker according to claim 1, wherein the counter-based frequency discriminator is further configured to reset the count value of the recovered clock signal and the count value of the local clock signal after sampling the count value of the recovered clock signal.

5. The digital clock frequency tracker according to claim 1, wherein the target value of the recovered clock signal is four, six, or eight times the target value of the local clock signal.

6. The digital clock frequency tracker according to claim 1, wherein the phase detector performs oversampling on the recovered clock signal by an integer multiple of four using the local clock signal according to the frequency division coefficient, and when the sampling result is 000, 010, 101, or 111, the phase detection result is 0, when the sampling result is 001 or 110, the phase detection result is −1, and when the sampling result is 011 or 100, the phase detection result is 1, and the phase detector sequentially outputs the phase detection results.

7. The digital clock frequency tracker according to claim 1, wherein the phase detector performs oversampling on the recovered clock signal by an integer factor that is not a multiple of four using the local clock signal according to the frequency division coefficient, when the sampling result is 000, 010, 101, or 111, the phase detection result is 0, when the sampling result is 001 or 110, the phase detection result is −1, and when the sampling result is 011 or 100, the phase detection result is 1, and the phase detector sequentially outputs the phase detection results starting from the first phase detection result with an interval of the integer factor that is not a multiple of four, and discards other phase detection results.

8. The digital clock frequency tracker according to claim 7, wherein the phase detector performs oversampling on the recovered clock signal by an integer factor that is not a multiple of four using the local clock signal according to the frequency division coefficient, wherein the oversampling is six-times oversampling.

9. A high-speed serial interface chip, comprising:
a clock-data recovery circuit at a receiving end, configured to recover a high-speed clock of the receiving end;
a first frequency divider, configured to divide the recovered high-speed clock to obtain a divided recovered clock signal;
a phase-locked loop at a transmitting end, configured to generate the high-speed clock of the transmitting end;
a second frequency divider, configured to divide the high-speed clock of the transmitting end to obtain a divided local clock signal; and
the digital clock frequency tracker according to claim 1.

10. The high-speed serial interface chip according to claim 9, the digital clock frequency tracker further comprises:
a frequency anomaly monitoring module, configured to receive the divided recovered clock signal and the divided local clock signal, set corresponding target values according to the frequency ratio of the recovered clock signal to the local clock signal, sample a count value of the recovered clock signal after a count value of the local clock signal reaches its corresponding target value, and when the difference between the count value of the recovered clock signal and the corresponding target value exceeds a predetermined range, disable the digital low-pass filter, and when the difference between the count value of the recovered clock signal and the corresponding target value is within the predetermined range, enable the digital low-pass filter.

11. The high-speed serial interface chip according to claim 10, wherein in the frequency anomaly monitoring module the target value of the recovered clock signal is four, six, or eight times the target value of the local clock signal, and the target values of the recovered clock signal and the local clock signal set in the frequency anomaly monitoring module are less than those set in the counter-based frequency discriminator.

12. The high-speed serial interface chip according to claim 9, wherein the counter-based frequency discriminator is further configured to reset the count value of the recovered clock signal and the count value of the local clock signal after sampling the count value of the recovered clock signal.

13. The high-speed serial interface chip according to claim 9, wherein the target value of the recovered clock signal is four, six, or eight times the target value of the local clock signal.

14. The high-speed serial interface chip according to claim 9, wherein the phase detector performs oversampling on the recovered clock signal by an integer multiple of four using the local clock signal according to the frequency division coefficient, and when the sampling result is 000, 010, 101, or 111, the phase detection result is 0, when the sampling result is 001 or 110, the phase detection result is −1, and when the sampling result is 011 or 100, the phase detection result is 1, and the phase detector sequentially outputs the phase detection results.

15. The high-speed serial interface chip according to claim 9, wherein the phase detector performs oversampling on the recovered clock signal by an integer factor that is not a multiple of four using the local clock signal according to the frequency division coefficient, when the sampling result is 000, 010, 101, or 111, the phase detection result is 0, when the sampling result is 001 or 110, the phase detection result is −1, and when the sampling result is 011 or 100, the phase detection result is 1, and the phase detector sequentially outputs the phase detection results starting from the first phase detection result with an interval of the integer factor that is not a multiple of four, and discards other phase detection results.

16. The high-speed serial interface chip according to claim 9, wherein the phase detector performs oversampling on the recovered clock signal by an integer factor that is not a multiple of four using the local clock signal according to the frequency division coefficient, wherein the oversampling is six-times oversampling.
